(19) United States
(12) Patent Application Publication
(10) Pub. No.: US 2019/0036301 A1
(43) Pub. Date: Jan. 31, 2019

(54) METHODS AND APPARATUS TO THERMALLY MANAGE HEAT SOURCES USING EUTECTIC THERMAL CONTROL

(71) Applicant: The Boeing Company, Chicago, IL (US)

(72) Inventor: Loyal Bruce Shawgo, O'Fallon, MO (US)

(21) Appl. No.: 15/660,629

(22) Filed: Jul. 26, 2017

(51) Int. Cl. H01S 5/024; H01S 3/04; C09K 5/06; F28D 15/02

(52) U.S. Cl. CPC H01S 5/02469; H01S 3/0405; F28F 3/02; C09K 5/066; F28D 15/0233; H01S 3/0407

(57) ABSTRACT

Methods and apparatus to thermally manage heat sources using eutectic thermal control are disclosed. A disclosed example apparatus includes a cooling block to be thermally coupled to a heat generation source of an aircraft, and eutectic metal alloy disposed within cavities of the cooling block.

### FIELD OF THE DISCLOSURE

This disclosure relates generally to thermal management and, more particularly, to methods and apparatus to thermally manage heat sources using eutectic thermal control.

### BACKGROUND

High-powered lasers, such as lasers that generate 1 kilowatt (kW) or more power, often dissipate relatively large amounts of waste heat during operation. As a result, corresponding cooling systems, such as compressor-based active recirculating systems and refrigeration systems, are typically employed to manage the significant heat loads generated by these lasers in a relatively short time. However, these cooling systems can have significantly high weight and volume requirements. Therefore, in applications such as aircraft or other vehicles, these weight and volume requirements can significantly impact weight or general operation (e.g. during flight) of an aircraft and, thus, negatively affect fuel efficiency and/or maneuverability.

### BRIEF DESCRIPTION OF THE DRAWINGS

FIG. 1 is an example aircraft in which the examples disclosed herein may be implemented.

FIG. 2 is cross-sectional view of an example cooling apparatus in accordance with the teachings of this disclosure.

FIG. 3 is a perspective cross-sectional view of an alternative example cooling apparatus in accordance with the teachings of this disclosure.

FIG. 4 is a flowchart representative of an example method to implement the examples disclosed herein.

FIG. 5 is a flowchart representative of an example method to produce the examples disclosed herein.

The figures are not to scale. Instead, to clarify multiple layers and regions, the thickness of the layers may be enlarged in the drawings. Wherever possible, the same reference numbers will be used throughout the drawing(s) and accompanying written description to refer to the same or like parts. As used in this patent, stating that any is in any way positioned on (e.g., positioned on, located on, disposed on, or formed on, etc.) another part, indicates that the referenced part is either in contact with the other part, or that the referenced part is above the other part with one or more intermediate part(s) located therebetween. Stating that any part is in contact with another part means that there is no intermediate part between the two parts.

### SUMMARY

An example apparatus includes a cooling block to be thermally coupled to a heat generation source of an aircraft, and eutectic metal alloy disposed within cavities of the cooling block.

An example method includes generating, via a laser generator, a laser output, where the laser generator is thermally coupled to a block including cavities that have a eutectic metal alloy disposed within.

Another example method includes defining cavities within a block to be thermally coupled to a laser generator, and providing a eutectic metal alloy to the cavities, where the eutectic metal alloy is to undergo a phase change when the heat generation source is operated.

### DETAILED DESCRIPTION

Methods and apparatus to thermally manage heat sources using eutectic thermal control are disclosed. Known cooling systems associated with high heat generation sources, such as cooling systems for low duty cycle lasers (e.g., pulse lasers, intermittent lasers, etc.), often include relatively large and heavy cooling equipment (e.g., active cooling systems, refrigeration systems, etc.). Accordingly, such cooling equipment can be difficult to implement on aircraft and/or vehicles due to their significant power requirements, as well as volumetric and weight requirements.

The examples disclosed herein provide a compact and lightweight solution to efficiently cool high power generation sources (e.g., intermittent heat generation sources, pulsed heat generations sources, etc.). In particular, the examples disclosed herein may be used to cool high power heat generation sources, including lasers, on vehicles, such as aircraft or land vehicles. The examples disclosed can be operated without complicated active cooling and/or refrigeration systems by utilizing eutectic metal alloys in cavities of solid objects, such as cooling blocks.

The examples disclosed herein include a structure or cooling block having at least one cavity that has a eutectic material and/or a eutectic metal alloy disposed within. For example, a eutectic metal alloy may be embedded in at least one cavity of a base material structure (e.g., multiple cavities within a cooling block composed of a base metal/metallic material) that is thermally coupled to a high power heat generation source (e.g., a laser). Accordingly, heat generated by the high heat power generation source may be transferred into latent heat of a eutectic metal alloy, thereby increasing conduction of the heat away from the high power heat generation source. In some examples, the eutectic metal alloy is incorporated within the high heat power generation source and a secondary cooling device is thermally coupled to the eutectic metal alloy.

In some examples, heat sink arrays are coupled to and/or integral with the cooling block. In some examples, fluid channels are present in the cooling block and/or a heat sink array so that fluid (e.g., a liquid such as water, a cooling gas, air, etc.) may flow therethrough. Additionally or alternatively, secondary channels or pores may fluidly couple the channels to respective external openings to enable the fluid to exit the cooling block and/or the respective heat sink array, thereby acting as an evaporative coolant, for example.

In some examples, an expansion material, such as a closed cell foam, is also disposed in a cavity of the cooling block in addition to the eutectic metal alloy. Accordingly, the expansion material may be implemented as a divider of the cavity and/or a disposed at a longitudinal end of the cavity.

In some examples, a cavity in the cooling block has an oval-shaped and/or generally oblong cross-sectional profile. In other examples, the cavity has a star-shaped cross-sectional profile. In some examples, the cooling block and/or assembly associated with the cooling block at least partially extends from and/or partially defines a fuselage or outer surface of an aircraft.

As used herein, the term “eutectic metal alloy” refers to an alloy or mixture of two or more base metal materials in which the mixture has a lower melting point than any of the base materials alone. As used herein, the term “laser generator” refers to a component or assembly that is associated with generating a laser output (e.g., a beam of laser light). Accordingly, the term “laser generator” can refer to a laser generating component, assembly or system including components that power the laser, as well as any component used to direct the laser output.

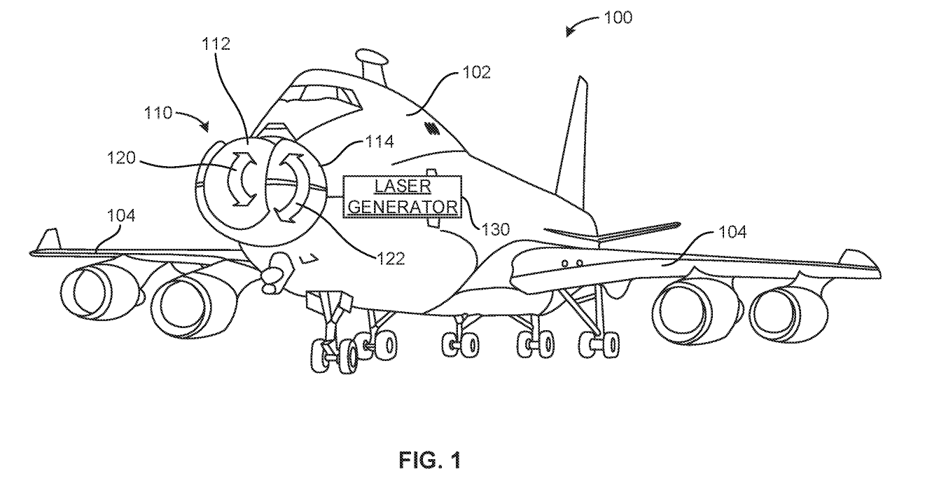

FIG. 1 is an example aircraft 100 in which the examples disclosed herein may be implemented. The example aircraft 100 of the illustrated example includes a fuselage 102 and wings 104 that are coupled thereto. The example fuselage 102 includes a laser assembly 110, which includes a first rotating radome 112 and a second rotating radome 114, both of which can be simultaneously rotated about multiple axes of rotation to aim a laser that is generated by a laser generator (e.g., a laser generation and aiming system) 130.

In operation, each of the radomes 112, 114 is rotated (e.g., independently rotated) in directions generally indicated by arrows 120, 122, respectively, to aim the laser output generated by the laser generator 130 during flight of the aircraft 100. In particular, the laser generator 130 generates a laser output once the radomes 112, 114 are properly oriented/aimed and a command has been issued to generate the laser output. During generation of the laser output, a significant amount of heat can be generated quickly. The examples disclosed herein enable compact and lightweight cooling of the laser generator 130 and/or the laser assembly 110 by efficiently dissipating the heat that is generated in a relatively short time duration.

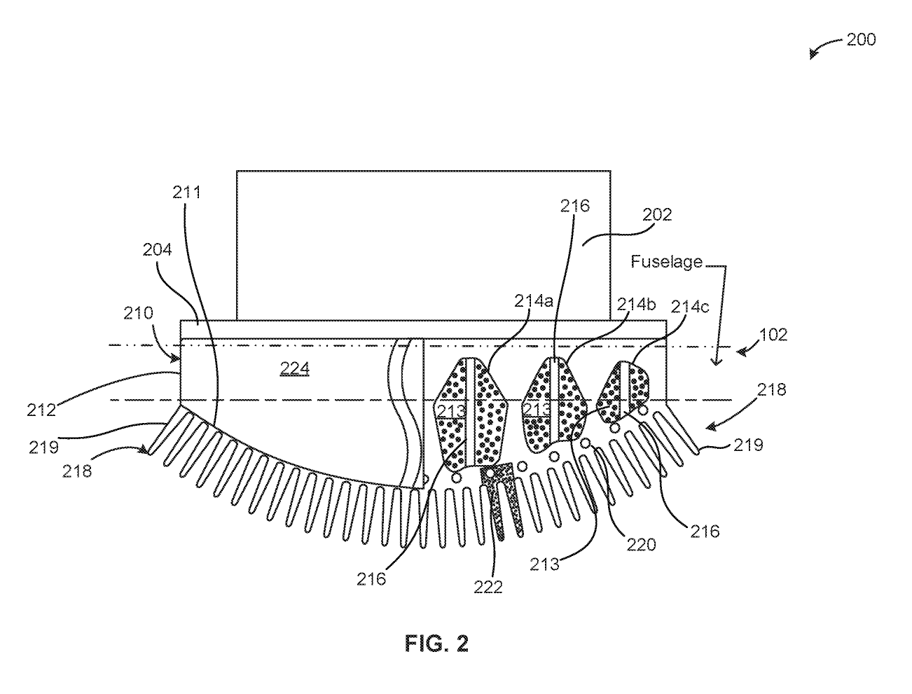

FIG. 2 is cross-sectional view of an example cooling apparatus 200 in accordance with the teachings of this disclosure. The example cooling apparatus 200 may be disposed on and/or partially define any surface (e.g., any external or internal surface) of the fuselage 102, the radomes 112, 114 and/or the example aircraft 100, in general.

The cooling apparatus 200 of the illustrated example includes a heat generating portion 202 of the laser generator 130 shown in FIG. 1, a base flange (e.g., a heat transfer plate, an interface layer, etc.) 204, and a block (e.g., a cooling block, an end plate, a heat sink interface, a heat conduction block/plate, etc.) 210. The example block 210 exhibits a curvature (e.g., a curved profile shape) 211 and includes a base portion (e.g., a base structure, a main body, etc.) 212, channels or cavities 214 (cavities 214a, 214b, 214c, etc.) that extend longitudinally into the view of FIG. 2 and include eutectic metal alloy material 213 disposed within. In some examples, each of the cavities 214 also includes an expansion material (e.g., a foam expansion material) 216, which is implemented as a divider (e.g., a center divider that extends generally along a direction into the view shown in FIG. 2) of the respective cavities 214 in this example. In examples where the expansion material 216 is present, the expansion material 216 can be implemented as a closed cell foam material. In other examples, the expansion material 216 may be implemented as an open cell foam material. However, any other appropriate material with a relatively high elasticity and/or sufficient durability in conjunction with the eutectic metal alloy material 213 may be used.

In this example, the block 210 defines, assembles to and/or includes a heat sink array 218, which includes ridge-shaped fins (e.g., converging or tapered ridge-shaped fins) 219. In some examples, the base portion 212 and/or the heat sink array 218 include flow channels (e.g., fluid flow channels) 220 that extend into the view of FIG. 2, as well as external fluid pathways (e.g., pores, secondary channels, bleed channels, evaporation channels, etc.) 222 that couple the fluid flow channels 220 and allow fluid to flow out of external surfaces. In some examples, only portions of the fins 219 are covered by the external fluid pathways 222. In other examples, a significant portion of (e.g., all of) the heat sink array 218 is covered by the external fluid pathways 222. In this example, the cavities 214 and a lateral end of the base portion 212 are covered by an end plate 224, which is shown as partially cut in FIG. 2 for clarity.

In operation, to increase movement and/or efflux of thermal energy away from the heat generating portion 202 and/or increase dissipation of the thermal energy, the eutectic metal alloy 213 that is disposed in the cavities 214 undergoes a phase change from a solid state to a liquid state when the thermal energy is conducted through the base portion 212. In particular, the thermal energy is at least partially dissipated into latent heat energy during this phase change, thereby increasing an effective heat conduction and energy absorption/dissipation (e.g., absorption of heat as the eutectic metal alloy 213 is undergoing a phase change until all of the eutectic metal alloy 213 has converted to the liquid state). Further, this phase change can require a significant amount of energy based on the properties of the eutectic metal alloy 213 and can occur in a relatively short time duration. As a result, relatively constant temperature may be maintained during the phase change.

According to the illustrated example, to maintain a relatively constant temperature distribution of the base portion 212, the laser generator 130, the base flange 204 and/or the heat generating portion 202, the eutectic metal alloy 213 composition is selected to phase shift based on an application-appropriate temperature. According to the illustrated example, the eutectic metal alloy 213 is composed of tin, lead and/or bismuth (e.g., primarily of bismuth). However, any appropriate alloy and/or compound may be used. In some other examples, a liquid eutectic solution (e.g., a eutectic salt solution) may be used to cool the base portion 212 by facilitating movement of heat without utilizing a phase change from solid to liquid in a manner similar to the example implementation of the eutectic metal alloy 313. In this example, the base portion 212 and the heat sink array 218 are composed of aluminum. However, in other examples, the base portion 212 and the heat sink array 218 may be composed of any appropriate alloy or material, such as beryllium, for example.

In some examples, to further enhance heat transfer and/or heat movement of heat away from the heat generating portion 202 (e.g., heat dissipation), fluid (e.g., water, evaporative coolants, air, or mixture thereof, etc.) flows through the flow channels 220. Additionally or alternatively, the fluid flows from the flow channels 220 to the fluid pathways 222, which can be implemented as pores and/or porous channels/openings of the respective fins 219, to exit from the cooling apparatus 200. In such examples, the fluid acts as an additional phase change material to further absorb heat energy. In some examples, the fluid is caused to flow through the flow channels prior to a laser out being generated (e.g., 1 second before, 500 milliseconds before, etc.)

In this example, each of the cavities 214 exhibits a relatively oblong cross-sectional profile (e.g., oval shape, a generally oblong irregular cross-sectional profile) that converges and/or narrows at respective ends of the cavities 214 closer to the base flange 204. Further, the example cavities 214 also exhibit a relatively wider portion that converges towards the heat sink array 218 and an outer surface of the fuselage 102. However, any appropriate cross-sectional profile shape may be used to define a cross-sectional profile of the cavities 214. In particular, an example shape profile may be a round shape, a triangular shape, a rectangular shape, a hexagonal shape, etc. In some examples, the cavities exhibit a flat or curved sheet geometry (e.g., a sheet-like shape) conforming to or replacing a mold line of the aircraft 100. In these examples, the cavities can be combined with a foam filler, such as the expansion material 216 to maintain contact between a eutectic material (e.g., the eutectic metal alloy 213) and a heat source or heat dissipating fins, for example, thereby increasing heat transfer during operation and to ensure that the eutectic material will not potentially lose contact with the enclosure/heat transfer base during cooling.

In this example, the fins 219 are integral with the base portion 212. In particular, the fins 219 of the illustrated example are molded or extruded with the base portion 212, as well as the cavities 214. However, in other examples, the fins 219 are assembled, bonded, welded and/or coupled to the base portion 212. In other examples, an active cooling system, such as a refrigeration system and/or refrigeration components are coupled to the base portion 212 to dissipate heat instead of the heat sink array 218.

In some examples, at least one of the heat sink array 218 or the base portion 212 extends out of the fuselage 102. Additionally or alternatively, at least a portion of the block 210, the base portion 212 and/or the fin array 218 defines an outer surface of the fuselage 102 and/or the aircraft 100. In some examples, the base portion 212 and/or the heat sink array 218 exhibits a curvature to match a curvature of an outer surface of the aircraft 100. In some examples, relative sizes of the cavities 214 vary across different portions of the base portion 212 (e.g., sizes of the channels increase away from the heat sink array 218 or vice-versa). In some examples, the cavities 214 do not significantly extend along a longitudinal direction of the base portion 212 (e.g., the cavities 214 are axisymmetric and/or are generally shaped as non-contiguous pockets, etc.).

While the base flange 204 is shown in the illustrated example of FIG. 2, in other examples, the heat generating portion 202 is directly coupled to the block 210. While the fins 219 are shown as generally ridge-shaped in this example, the fins 219 may have any other appropriate geometry including pin shaped, contoured, grid-like, etc. While the eutectic material in this example is implemented as the eutectic metal alloy 213, any appropriate eutectic material or solution that is not a metal alloy may be used.

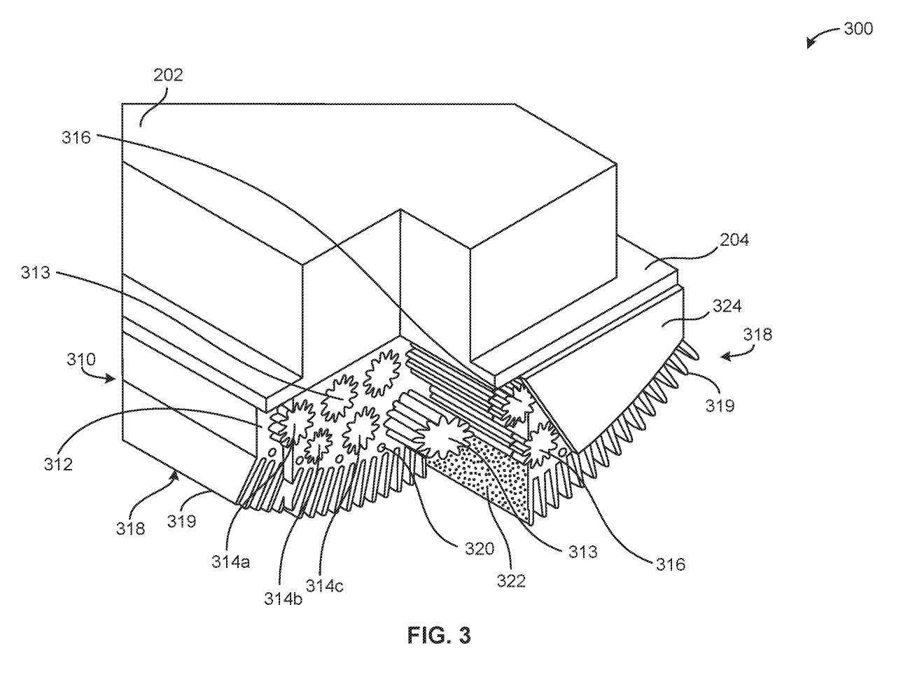

FIG. 3 is a perspective cross-sectional view of an alternative example cooling apparatus 300 in accordance with the teachings of this disclosure. The cooling apparatus 300 is similar to the cooling apparatus described 200 above in connection with FIG. 2 but, instead, includes a different cavity structure/geometry and expansion material placement at a lateral end instead of extending along a significant portion of a cavity length. The cooling apparatus 300 of the illustrated example includes the heat generating portion 202, the base flange 204, a block 310 with a base portion 312, eutectic metal alloy 313 disposed in respective star-shaped channels (e.g., channels having a generally star-shaped cross-sectional profile) or cavities 314 (314a, 314b, 314c, etc.), expansion material (e.g., an expansion end stop) 316, and a heat sink array 318 with respective fins 319. In some examples, at least one of the base portion 312 and/or the heat sink array 318 includes fluid channels 320 and corresponding external openings and/or pores 322. In some examples, an end plate 324 is positioned at a lateral end of the base portion 312.

According to the illustrated example, the cross-sectional profiles (e.g., channel shape profiles) of the cavities 314 are generally star-shaped to increase surface area contact between the eutectic metal alloy 313 and the base portion 312, thereby increasing heat transfer therebetween. In particular, the cavities 314 exhibit a 12-point star-shaped profile. However, any appropriate star-shaped profile pattern may be used (e.g., 5-point, 6-point, 10-point, 15-point, etc.). Alternatively, any other appropriate channel geometry shape may be used (e.g., triangular, rectangular, square, circular, elliptical, pentagonal, hexagonal and/or octagonal, etc.). Additionally or alternatively, the cavities 314 may have varying sizes across a horizontal and/or vertical distance of the base portion 312 (as viewed in FIG. 3). In some examples, differently shaped profiles are used in the base portion 312 (e.g., a combination of triangular and rectangular shaped cross-sectional profiles).

In contrast to the example cooling apparatus 200 of FIG. 2, the expansion material 316 is disposed at a lateral end of base portion 312 proximate the end plate 324 instead of subdividing the cavities 214, as shown in FIG. 2. Accordingly, the eutectic metal alloy 313 of the illustrated example can expand along a longitudinal length of the cavities 314, thereby compressing the expansion material 316 against the end plate 324. Accordingly, the eutectic metal alloy 313 can maintain contact with walls of the base portion 312 without being subdivided, which enables greater transfer across the eutectic metal alloy 313.

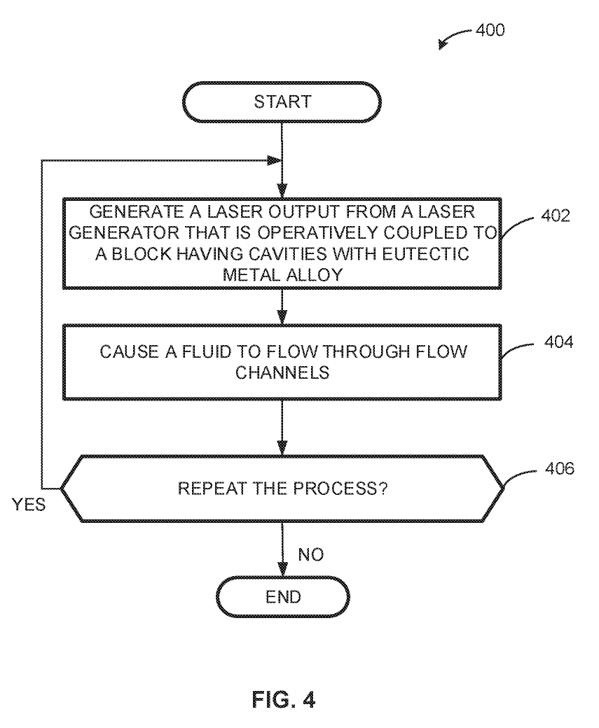

FIG. 4 is a flowchart representative of an example method 400 to implement the examples disclosed herein. The example method 400 begins as a heat generation source, such as the laser generator 130 of the aircraft 100, is caused to generate a laser output (e.g., by a flight or weapon control system). Once the laser output is generated for a relatively short duration, a relatively large heat flux necessitates relatively quick dissipation to prevent overheating of components and/or structures of a vehicle.

According to the illustrated example, the laser is generated by the laser generator 130, which is thermally and/or operatively coupled to a block (e.g., the block 210, the block 310) having cavities (e.g., the cavities 214, the cavities 314), in which a eutectic metal alloy (e.g., the eutectic metal alloy 213, the eutectic metal alloy 313) is disposed (block 402).

In some examples, a fluid is caused to flow through flow channels (e.g., the flow channels 220, the flow channels 320) of the block (block 404). In particular, a liquid and/or gas may flow through the flow channels to exit to via an opening of an external surface. In other examples, the fluid does not exit from the opening.

Next, it is determined whether to repeat the process (block 406). If the process is to be repeated (block 406), control of the process returns to block 402. Otherwise, the process ends.

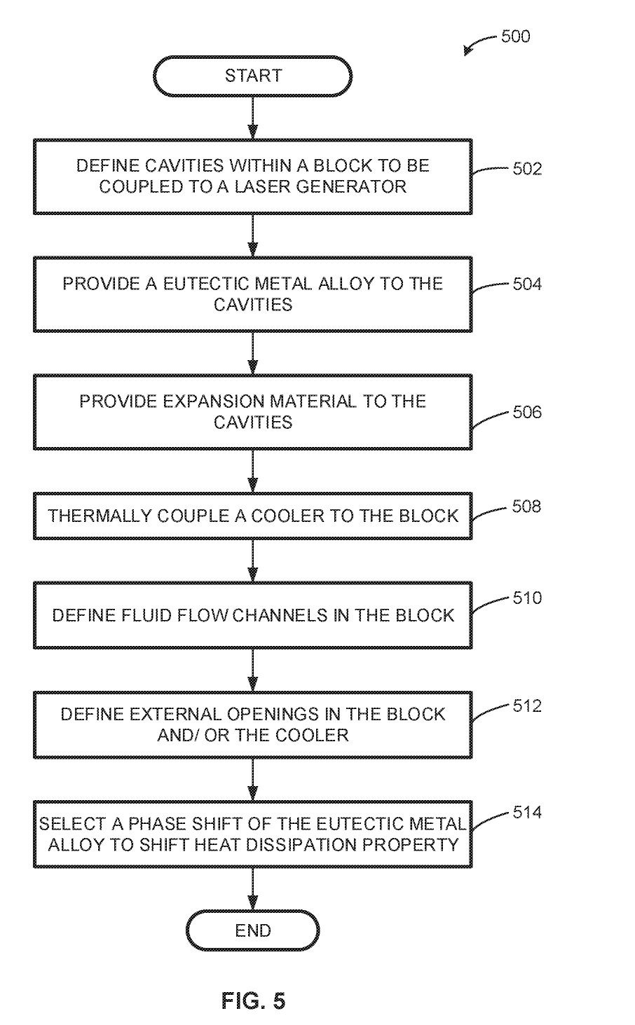

FIG. 5 is a flowchart representative of an example method 500 to produce the examples disclosed herein. According to the illustrated example, a cooling block is to be thermally coupled (e.g., directly or indirectly coupled) to a heat generation source, which is a laser generator (e.g., the laser generator 130 of FIG. 1).

According to the illustrated example, cavities (e.g., the cavities 214, the cavities 314) are defined in the block (block 502). In other examples, the cavities may be defined in combination with manufacturing of the block (e.g., when the block is molded, cast and/or extruded).

Next, a eutectic metal alloy (e.g., the eutectic metal alloy 213, the eutectic metal alloy 313) and/or eutectic material is provided to the cavities (block 504). The eutectic metal alloy may be applied and/or deposited to the cavities in a molten or liquid state (e.g., a melted state) or any other appropriate insertion or deposition process. In some examples, the eutectic metal alloy is sealed into the cavities by a secondary process of the block (e.g., a swaging or welding process of a base portion of the block).

In some examples, an expansion material and/or an expansion block or partition is provided to and/or within the cavities (block 506). In this example, the expansion material is provided as a divider or partition that divides a volume in the cavity into two relatively equal volumes through a significant portion of a longitudinal length of each of the cavities (e.g., the entire longitudinal length of the cavities). In some examples, the expansion material defines two symmetric portions of the volume. In other examples, the expansion material is positioned in at least a longitudinal end of a respective cavity.

According to the illustrated example, a cooler is coupled and/or thermally coupled to the block (block 508). In this example, the cooler is a powered cooler, such as a refrigeration assembly component (e.g., a refrigeration plate) and/or a Peltier cooler. In other examples, the cooling system is a passive cooler, such as the heat sink array 218 or the heat sink array 318 of FIGS. 2 and 3, respectively.

In some examples, fluid flow channels (e.g., the flow channels 220, the flow channels 320) are defined in the block (block 510). For example, the channels may be defined to extend along a longitudinal direction of the cavities in which the eutectic metal alloy is disposed.

Additionally or alternatively, in some examples, external openings are defined in the block and/or the cooler (block 512). In particular, the openings are fluidly coupled to the fluid flow channels and define an exit pathway for the fluid flowing through the channels so that this fluid can evaporatively cool the block in some examples.

In some examples, a phase shift of the eutectic metal alloy is selected to shift a heat dissipation property (block 514). For example, the eutectic metal alloy is changed or adjusted (e.g., a mixture of the metals selected for the alloy, differing ratios of base metals, etc.) to adjust for specific application(s), design needs and/or operating conditions. For example, the eutectic metal alloy may be compositionally altered and/or replaced to vary a heat dissipation property of the example block.

From the foregoing, it will be appreciated that example methods, apparatus and articles of manufacture have been disclosed that provide lightweight and effective cooling for heat generation sources that have significant heat fluxes, which are generated relatively quickly. The examples disclosed herein enable integration of high power heat generation sources, such as lasers, onto vehicles without requiring the typical large and heavy cooling equipment that is usually employed.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent. While the examples described herein are related to aircraft lasers, the examples disclosed herein may be applied to any application including a heat generating device. Further, the examples disclosed herein do not have to specifically apply to vehicles and can apply to any appropriate heat generation applications.

What is claimed is:

1. An apparatus comprising:
a cooling block to be thermally coupled to a heat generation source of an aircraft; and
eutectic metal alloy disposed within cavities of the cooling block.

2. The apparatus as defined in claim 1, further including a heat sink array to be thermally coupled to or integral with the cooling block.

3. The apparatus as defined in claim 2, wherein the heat sink array extends past an outer surface of a fuselage of the aircraft.

4. The apparatus as defined in claim 1, further including a foam expansion material disposed within the cavities.

5. The apparatus as defined in claim 1, further including fluid flow channels disposed in the cooling block.

6. The apparatus as defined in claim 5, further including fluid pathways that fluidly couple the fluid flow channels to an external surface to allow fluid to flow out from the external surface.

7. The apparatus as defined in claim 1, wherein the eutectic metal alloy includes at least one of bismuth, lead or tin.

8. The apparatus as defined in claim 1, wherein the cooling block includes at least one of aluminum or beryllium.

9. The apparatus as defined in claim 1, wherein the cavities have a generally star-shaped cross-sectional profile.

10. The apparatus as defined in claim 1, wherein the cavities have a generally oblong irregular cross-sectional profile.

11. The apparatus as defined in claim 1, wherein the cavities exhibit a sheet-like shape at least partially defining an outer surface of the aircraft.

12. A method comprising:
generating, via a laser generator, a laser output, wherein the laser generator is thermally coupled to a block including cavities that have a eutectic metal alloy disposed within.

13. The method as defined in claim 12, further including causing a fluid to flow in channels proximate a heat sink array that is thermally coupled to the block, wherein the fluid is to flow out of the heat sink array via external openings.

14. The method as defined in claim 13, wherein the fluid is caused to flow out of the external openings prior to the laser output being generated.

15. The method as defined in claim 13, wherein the external openings include pores disposed on or within fins of the heat sink array.

16. The method as defined in claim 13, wherein the fluid includes an evaporative coolant.

17. A method comprising:
defining cavities within a block to be thermally coupled to a heat generation source of an aircraft; and
providing a eutectic metal alloy to the cavities, wherein the eutectic metal alloy is to undergo a phase change when the heat generation source is operated.

18. The method as defined in claim 17, further including coupling a heat sink array to the block or defining the heat sink array in the block.

19. The method as defined in claim 18, further including defining channels in the block or the heat sink array for fluid to flow therethrough.

20. The method as defined in claim 19, further including defining external openings in the heat sink array to allow the fluid to flow out from the heat sink array via the external openings.

21. The method as defined in claim 17, further including selecting a phase shift of the eutectic metal alloy to vary a heat dissipation property of the eutectic metal alloy.

22. The method as defined in claim 17, wherein defining the cavities including defining a sheet that at least partially defines an outer surface of the aircraft.
